(19) United States
(12) Patent Application Publication
(10) Pub. No.: US 2008/0142826 A1
(43) Pub. Date: Jun. 19, 2008

(54) ELECTROLUMINESCENT DEVICE AND MANUFACTURING METHOD THEREOF

(76) Inventors: Chuan-Chia Cheng, Taoyuan Hsien (TW); Shih-Peng Chen, Taoyuan Hsien (TW); Hsueh-Kuo Liao, Taoyuan Hsien (TW); Ching-Chuan Shiue, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 11/944,340

(22) Filed: Nov. 21, 2007

(30) Foreign Application Priority Data
Dec. 18, 2006 (TW) 095147370

(51) Int. Cl. H01L 33/00

(52) U.S. Cl. 257/98; 438/29; 257/E33.067

(57) ABSTRACT

An electroluminescent device includes a heat-conductive substrate, a heat-conductive adhering layer, a heat-conductive insulating layer, a reflective layer, a light-emitting diode element, a first contacting electrode and a second contacting electrode. The heat-conductive adhering layer is formed on the heat-conductive substrate. The heat-conductive insulating layer is formed on the heat-conductive adhering layer. The reflective layer is formed on the heat-conductive insulating layer. The light-emitting diode element is formed on the reflective layer, and a part of the reflective layer is exposed from the light-emitting diode element. The first contacting electrode is disposed on the light-emitting diode element. The second contacting electrode is disposed on the exposed reflective layer. A manufacturing method of the electroluminescent device is also disclosed.

### CROSS REFERENCE TO RELATED APPLICATIONS

This Non-provisional application claims priority under 35 U.S.C. §119(a) on Patent Application No. 095147370, filed in Taiwan, Republic of China on Dec. 18, 2006, the entire contents of which are hereby incorporated by reference.

### BACKGROUND OF THE PRESENT INVENTION

1. Field of Invention

The present invention relates to a luminescent device and a manufacturing method thereof, and more particularly to an electroluminescent device and a manufacturing method thereof.

2. Related Art

In recent years, the advances in electroluminescent technology push the material and manufacturing techniques of light emitting diode (LED) forward. Their applications range from indicators of computers or home appliances, backlight sources of liquid crystal displays, to traffic lights or vehicle lights. They may even be used as light sources of illumination. However, with increasing light emitting power, the LED also produces more heat. If such heat cannot be properly and effectively dissipated, the light emitting efficiency thereof will be lowered.

A conventional LED is formed by a dual attachment procedure. It involves the steps of growing an epitaxy layer on a temporary substrate, transferring the epitaxy layer to a glass substrate; removing the temporary substrate; coating a mirror reflective layer on the epitaxy layer; attaching the epitaxy layer on a permanent substrate; and removing the glass substrate.

As shown in FIG. 1A, a conventional LED 1 is formed in accordance with the above-mentioned steps. The LED 1 is constituted by a permanent substrate 11, an organic adhering layer 12, a mirror reflective layer 13 and an epitaxy layer 14.

The epitaxy layer 14 is constituted by a p-type doped layer 141, a light emitting layer 142 and an n-type doped layer 143. In addition, a p-type electrode 151 is disposed on the p-type doped layer 141, and an n-type electrode 152 is disposed on the n-type doped layer 143. The material of the organic adhering layer 12 is generally PR, epoxy, polyimide, the coefficient of thermal conductivity of which is usually between 0.1 W/mk and 0.3 W/mk. Therefore, it is difficult to remove the heat generated from the LED 1. When the permanent substrate 11 is a metal, short circuits are likely to happen between the permanent substrate 11 and the epitaxy layer 14.

As shown in FIG. 1B, another conventional LED 2 is constituted by a metal reflective layer 22, a eutectic adhering layer 23, a transparent conductive layer 24 and an epitaxy layer 25 formed on a permanent substrate 21 in sequence. The epitaxy layer 25 is constituted by a p-type doped layer 251, a light emitting layer 252 and an n-type doped layer 253 in sequence. The n-type doped layer 253 is in contact with part of the transparent conductive layer 24. An n-type electrode 262 is disposed on another part of the transparent conductive layer 24. A p-type electrode 261 is disposed on the p-type doped layer 251.

The eutectic adhering layer 23 is formed by thermal pressing two metal layers 231, 232, thereby enhancing the bonding with the transparent conductive layer 24 and the metal reflective layer 22. However, the temperature required for the eutectic process is usually higher than 300˜400° C. This affects a certain effect on the epitaxy layer 25, which lowering its light emitting efficiency.

### SUMMARY OF THE PRESENT INVENTION

The present invention provides an electroluminescent device and a manufacturing method thereof that can provide a good heat dissipation path for removing heat generated therefrom, lower the temperature and raise the light emitting efficiency thereof.

An electroluminescent device according to the present invention includes a heat-conductive adhering layer, a heat-conductive substrate, a reflective layer, a light emitting diode (LED) element, a first contacting electrode and a second contacting electrode. The heat-conductive substrate is disposed on one side of the heat-conductive adhering layer. The reflective layer is formed on the other side of the heat-conductive adhering layer. The LED element is formed on the reflective layer and exposes a part of the reflective layer. The LED element includes a first semiconductor layer, a light emitting layer and a second semiconductor layer in sequence. The second semiconductor layer is in contact with the reflective layer. The first contacting electrode is electrically connected with the first semiconductor layer. The second contacting electrode is disposed on the exposed part of the reflective layer and electrically connected with the reflective layer.

Further, when the heat-conductive substrate is made by an electrically conductive material, the electroluminescent device can further include a heat-conductive insulating layer disposed between the heat-conductive adhering layer and the reflective layer or disposed between the heat-conductive substrate and the heat-conductive adhering layer so as to prevent short circuit between the LED element and the heat-conductive substrate.

A manufacturing method of an electroluminescent device according to the present invention includes the steps of forming a light emitting diode (LED) element on a plate, wherein the LED element includes a first semiconductor layer formed on the plate, a light emitting layer and a second semiconductor layer in sequence; forming a reflective layer on the LED element; forming a heat-conductive adhering layer on the reflective layer; attaching a heat-conductive substrate on the heat-conductive adhering layer; and removing the plate.

The manufacturing method of the electroluminescent device can further include a step of forming a heat-conductive insulating layer between the reflective layer and the heat-conductive adhering layer, or forming the heat-conductive insulating layer between the heat-conductive adhering layer and the heat-conductive substrate. This can prevent short circuit between the LED element and the heat-conductive substrate.

In the manufacturing method of the electroluminescent device, the material of the heat-conductive substrate includes Si, GaAs, GaP, SiC, BN, Al, AlN, Cu, or their combinations. The material of the heat-conductive adhering layer can be a bonding material, such as tin paste, tin-silver paste, silver paste, alloys, or a eutectic bonding material. The material of the heat-conductive insulating layer can be AlN, SiC or a high thermal conductivity insulating material.

As mentioned above, an electroluminescent device and a manufacturing method thereof according to the present invention utilize the heat-conductive adhering layer, the heat-conductive substrate and even the heat-conductive insulating layer with high coefficient of thermal conductivity to effectively dissipate heat generated from the LED element to the environment. It thereby raises the light emitting efficiency of the electroluminescent device.

### BRIEF DESCRIPTION OF THE DRAWINGS

The present invention will become more fully understood from the detailed description given herein below illustration only, and thus is not limitative of the present invention, and wherein:

FIG. 1A is a schematic diagram showing a conventional LED;

FIG. 1B is a schematic diagram showing another conventional LED;

FIG. 2 is a flowchart showing a manufacturing method of an electroluminescent device according to a first embodiment of the present invention;

FIGS. 3A to 31 are schematic diagrams showing the electroluminescent device in each step in FIG. 2;

FIG. 4 is a flowchart showing another manufacturing method of an electroluminescent device according to a second embodiment of the present invention; and

FIGS. 5A to 5I are schematic diagrams showing the electroluminescent device in each step in FIG. 4.

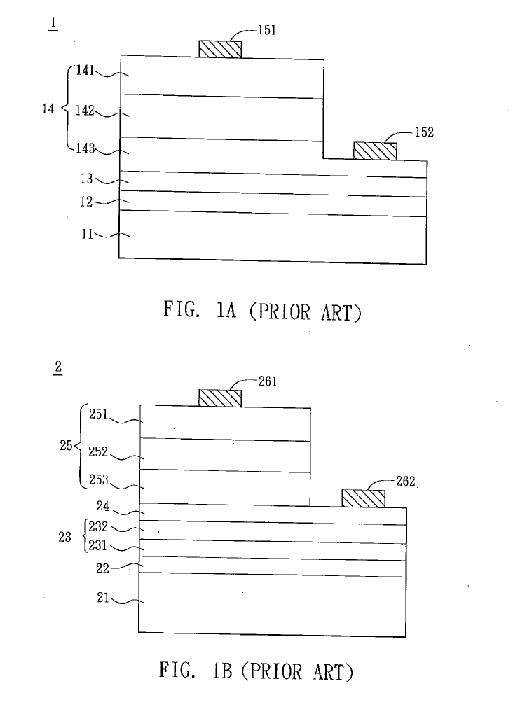

### DETAILED DESCRIPTION OF THE PRESENT INVENTION

The present invention will be apparent from the following detailed description, which proceeds with reference to the accompanying drawings, wherein the same references relate to the same elements.

This specification uses a first embodiment and a second embodiment to briefly explain an electroluminescent device and a manufacturing method thereof. Throughout this specification, the electroluminescent device is a light emitting diode (LED) as an example in these embodiments.

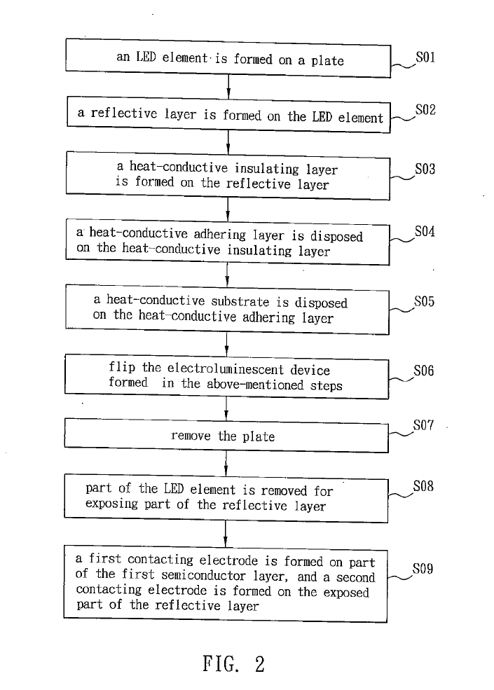

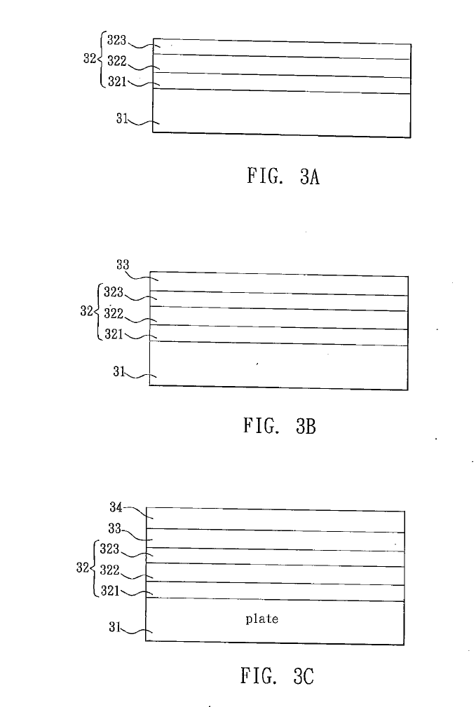

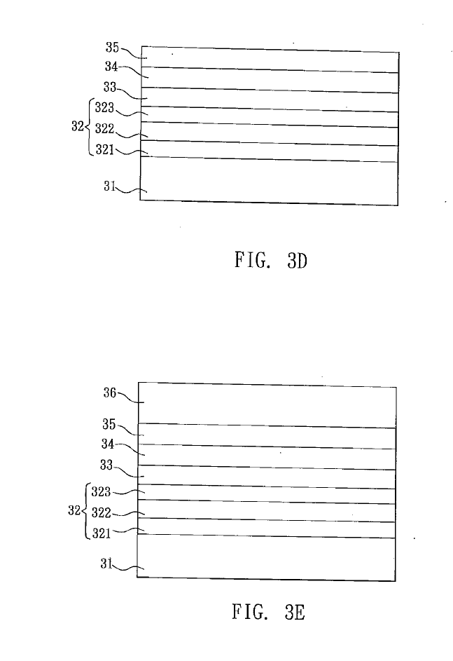

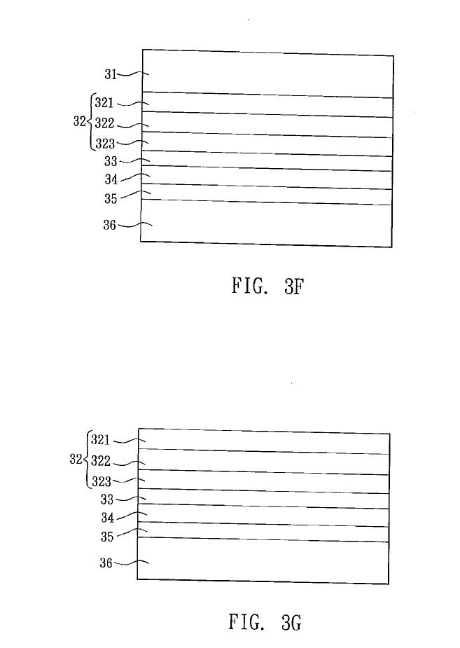

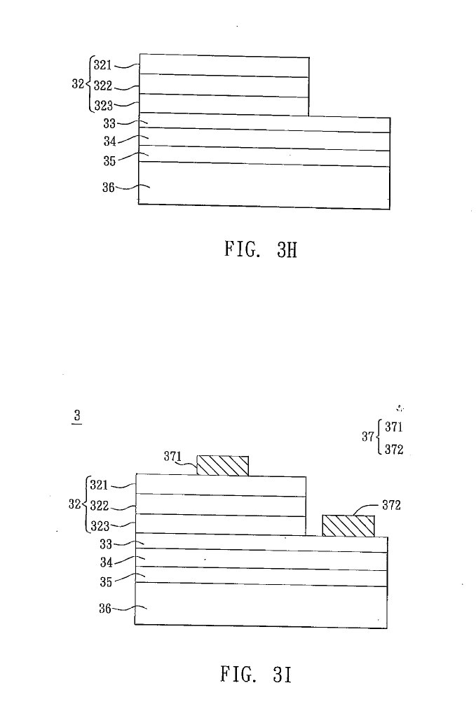

As shown in FIG. 2, a manufacturing method of an electroluminescent device according to a first embodiment of the present invention includes steps S01 to S09. Please refer simultaneously to FIGS. 3A to 3I. The following paragraphs explain in detail the electroluminescent device 3 and the manufacturing method thereof according to the first embodiment.

As shown in FIG. 3A, an LED element 32 is formed on a plate 31 in step S01. The plate 31 can be an epitaxy plate. Before use, its surface has to be cleansed by acetone and alcohol, followed by water rinse and dried by nitrogen (N₂) gas. Besides, the LED element 32 includes a first semiconductor layer 321, a light emitting layer 322 and a second semiconductor layer 323 in sequence. The first semiconductor layer 321 is formed on the plate 31. In this embodiment, the first semiconductor layer 321 is an n-type doped layer. The second semiconductor layer 323 is a p-type doped layer.

As shown in FIG. 3B, a reflective layer 33 is formed on the LED element 32 in step S02. More explicitly, the reflective layer 33 is formed on the second semiconductor layer 323 of the LED element 32. In this embodiment, the reflective layer 33 can be an ohmic contact metal reflective layer. In addition to reflecting light emitted from the LED element 32, it has the property of low resistance so that the electrical current is more evenly distributed. Moreover, the material of the reflective layer 33 includes Pt, Au, Ag, Pd, Ni, Cr, Ti Al or their combinations.

As shown in FIG. 3C, a heat-conductive insulating layer 34 is formed on the reflective layer 33 in step S03. In this embodiment, the heat-conductive insulating layer 34 can be formed on the reflective layer 33 by reaction sputtering, non-reaction sputtering or high-temperature nitridation. The material of the heat-conductive insulating layer 34 can be AlN, SiC or a high thermal conductivity insulating material. The coefficient of thermal conductivity of AlN is about 200˜230 W/mk, whereas the coefficient of thermal conductivity of SiC is about 300˜490 W/mk.

As shown in FIG. 3D, a heat-conductive adhering layer 35 is formed on the heat-conductive insulating layer 34 in step S04. That is, the heat-conductive adhering layer 35 may or may not have direct contact with the reflective layer 33. In the former case, the heat-conductive insulating layer 34 can either be not required. Here since the heat-conductive insulating layer 34 has been formed on the reflective layer 33, the heat-conductive adhering layer 35 is formed on the heat-conductive insulating layer 34 by screen printing, spin coating, dispensing or PVD process. The material of the heat-conductive adhering layer 35 is a bonding material, such as tin paste, tin-silver paste, silver paste, alloys, or a eutectic bonding material.

As shown in FIG. 3E, a heat-conductive substrate 36 is attached on the heat-conductive adhering layer 35 in step S05. The heat-conductive substrate 36 may or may not have direct contact with the heat-conductive adhering layer 35. Here the heat-conductive adhering layer 35 is formed on the heat-conductive insulating layer 34. Therefore, the heat-conductive substrate 36 is directly attached onto the heat-conductive adhering layer 35. The material of the heat-conductive substrate 36 includes Si, GaAs, GaP, SiC, BN, Al, AlN, Cu, or their combinations.

It should be noted that the heat-conductive adhering layer 35 can also be formed on the heat-conductive substrate 36 by screen printing, spin coating, dispensing, or PVD process before it is attached onto the heat-conductive insulating layer 34. The sequence of these steps is not restricted by the present invention.

As shown in FIG. 3F, step S06 flips the electroluminescent device 3 formed in the above-mentioned steps. Afterwards, as shown in FIG. 3G, step S07 removes the plate 31. The plate 31 can be removed by laser lift-off process.

As shown in FIG. 3H, part of the LED element 32 is removed for exposing part of the reflective layer 33 in step S08. In this embodiment, the removal is done by etching as an example. More explicitly, removing part of the LED element 32 include the steps of forming a photoresist layer on the first semiconductor layer 321; exposing the photoresist layer by a light, such as an ultraviolet (UV) light, via a mask; removing a part of the photoresist layer to form a patterned photoresist layer; removing a part of the first semiconductor layer 321, a part of the light emitting layer 322 and a part of the second semiconductor layer 323; and removing the patterned photoresist layer to expose the part of the reflective layer 33. It should be noted that the photoresist layer can be made of positive photoresist or negative photoresist. The difference is either the V exposed photoresist or the unexposed photoresist is to be removed. Since this is a well-known etching technology, it is not further described herein.

In final, it is the step of forming the contacting electrodes 37. As shown in FIG. 3I, a first contacting electrode 371 is formed on part of the first semiconductor layer 321, and a second contacting electrode 372 is formed on the exposed part of the reflective layer 33 in step S09. This completes the process of forming the electroluminescent device 3.

In this embodiment, the above-mentioned steps can be performed under a temperature ranging between 25° C. and 300° C. Therefore, the present invention involves only low-temperature processes, and is less likely to affect the yield of the LED elements 32. It is worth mentioning that if the heat-conductive substrate 36 is made of an insulating material, no heat-conductive insulating layer 34 is required. Therefore, the step of forming the heat-conductive insulating layer 34 can be omitted.

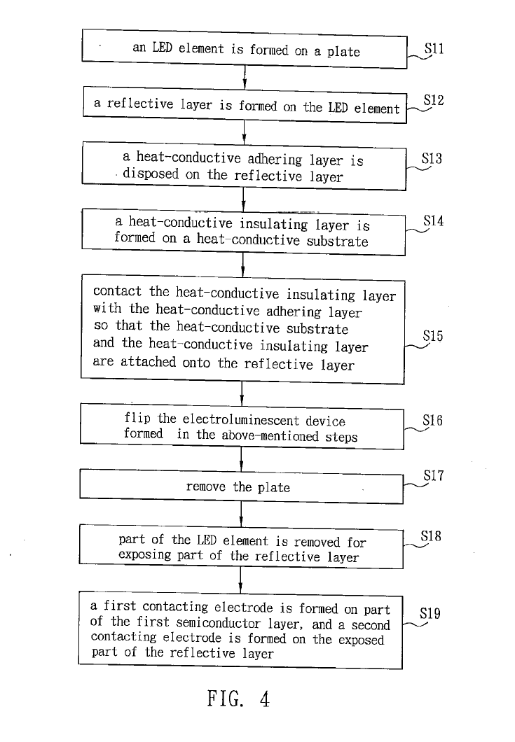

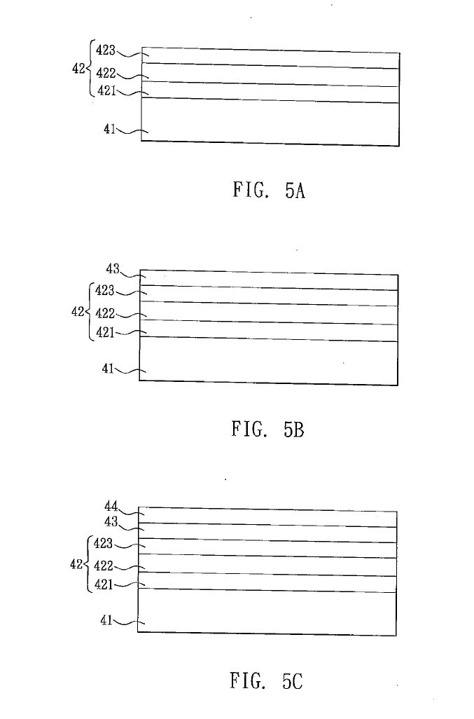

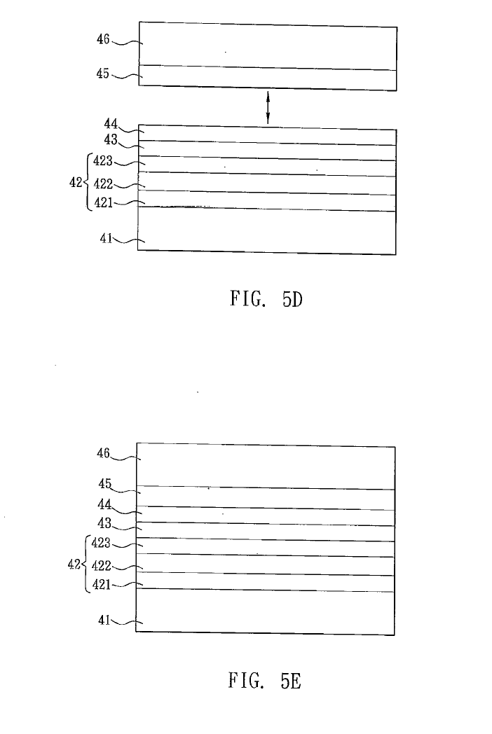

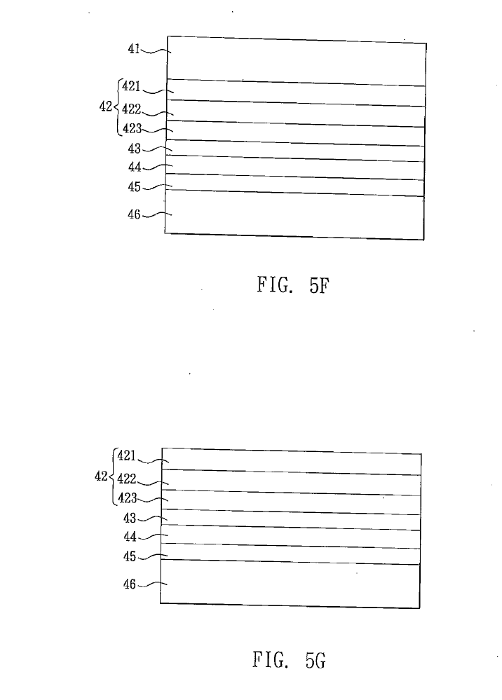

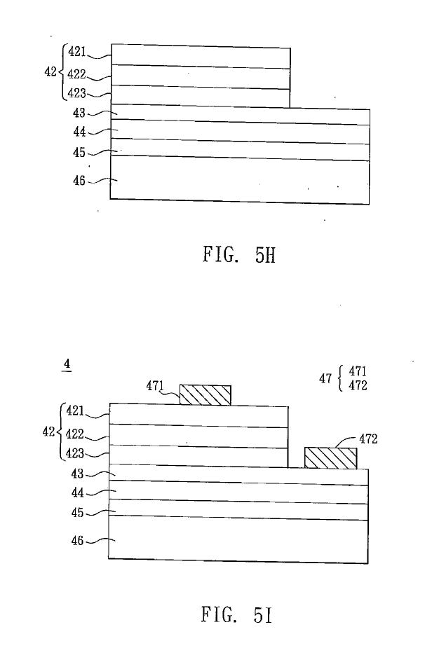

As shown in FIG. 4, a manufacturing method of an electroluminescent device according to a second embodiment of the present invention includes steps S11 to S19. Please refer simultaneously to FIGS. 5A to 5I. The following paragraphs explain in detail the electroluminescent device 4 and the manufacturing method thereof according to the second embodiment.

As shown in FIGS. 5A and 5B, steps S11 and S12 are the same as steps S01 and S02 in the first embodiment. Therefore, they are not further described here. That is, an LED element 42 is formed on a plate 41 in step S11, and the LED element 42 includes a first semiconductor layer 421, a light emitting layer 422 and a second semiconductor layer 423 in sequence. The first semiconductor layer 421 is formed on the plate 41. A reflective layer 43 is formed on the LED element 42 in step S12.

As shown in FIG. 5C, a heat-conductive adhering layer 44 is formed on the reflective layer 43 in step S13. That is, the heat-conductive adhering layer 44 may or may not have direct contact with the reflective layer 43. Here the heat-conductive adhering layer 44 is formed on the reflective layer 43 by screen printing, spin coating, dispensing or PVD process. The material of the heat-conductive adhering layer 44 is a bonding material, such as tin paste, tin-silver paste, silver paste, alloys, or a eutectic bonding material.

As shown in FIG. 5D, a heat-conductive insulating layer 45 is formed on a heat-conductive substrate 46 in step S14. In this embodiment, the heat-conductive insulating layer 45 can be formed on the heat-conductive substrate 46 by reaction sputtering, non-reaction sputtering or high-temperature nitridation. The material of the heat-conductive insulating layer 45 can be AlN, SiC or a high thermal conductivity insulating material. The coefficient of thermal conductivity of AlN is about 200˜230 W/mk, whereas the coefficient of thermal conductivity of SiC is about 300˜490 W/mk. Besides, the material of the heat-conductive substrate 46 includes Si, GaAs, GaP, SiC, BN, Al, AlN, Cu, or their combinations.

As shown in FIG. 5E, step S15 contacts the heat-conductive insulating layer 45 with the heat-conductive adhering layer 44 so that the heat-conductive substrate 46 and the heat-conductive insulating layer 45 are attached onto the reflective layer 43.

It should be noted that the heat-conductive adhering layer 44 can also be formed on the heat-conductive insulating layer 45 by screen printing, spin coating, dispensing, or PVD process before it is attached onto the reflective layer 43. The sequence of these steps is not restricted by the present invention.

As shown in FIGS. 5F to 5I, steps S16 to S19 are the same as steps S06 to S09 in the first embodiment. Therefore, they are not further described here. That is, step S16 flips the electroluminescent device 4 formed in the above-mentioned steps. Step S17 removes the plate 41. Part of the LED element 42 is removed for exposing part of the reflective layer 43 in step S18. In final, it is the step of forming the contacting electrodes 47. A first contacting electrode 471 is formed on a part of the first semiconductor layer 421, and a second contacting electrode 472 is formed on the exposed part of the reflective layer 43 in step S19. This completes the process of forming the electroluminescent device 4.

In this embodiment, removing part of the LED element 42 include the steps of forming a photoresist layer on the first semiconductor layer 421; exposing the photoresist layer by a light via a mask; removing part of the photoresist layer to form a patterned photoresist layer; removing a part of the first semiconductor layer 421, a part of the light emitting layer 422 and a part of the second semiconductor layer 423; and removing the patterned photoresist layer to expose part of the reflective layer 43.

In summary, an electroluminescent device and a manufacturing method thereof according to the present invention utilize the heat-conductive adhering layer, the heat-conductive substrate and even the heat-conductive insulating layer with high coefficient of thermal conductivity to effectively dissipate heat generated from the LED element to the environment. It thereby raises the light emitting efficiency of the electroluminescent device. In addition, since forming the heat-conductive adhering layer by screen printing, spin coating, dispensing or PVD process is a well-known and cheap method, and the production cost can be decreased while the yield can be increased. Moreover, forming the heat-conductive insulating layer between the heat-conductive substrate and the LED element can effectively prevent short circuit between them as well as enhance heat dissipation. Finally, utilizing the metal reflective layer with ohmic contact function to reflect light generated from the LED element can raise the external light extracting efficiency of the electroluminescent device.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A manufacturing method of an electroluminescent device, comprising steps of:
forming a light emitting diode (LED) element on a plate, the LED element comprising a first semiconductor layer formed on the plate, a light emitting layer and a second semiconductor layer in sequence;
forming a reflective layer on the LED element;
forming a heat-conductive adhering layer on the reflective layer;
attaching a heat-conductive substrate on the heat-conductive adhering layer; and
removing the plate.

2. The manufacturing method of claim 1, wherein the first semiconductor layer is an n-type doped layer, and the second semiconductor layer is a p-type doped layer.

3. The manufacturing method of claim 1, further comprising a step of:
forming a heat-conductive insulating layer on the reflective layer or the heat-conductive substrate.

4. The manufacturing method of claim 3, wherein the heat-conductive adhering layer is formed by screen printing, spin coating, dispensing or PVD process, and the heat-conductive adhering layer is formed on the heat-conductive insulating layer and attached with the heat-conductive substrate, or the heat-conductive adhering layer is formed on the heat-conductive substrate and attached with the heat-conductive insulating layer.

5. The manufacturing method of claim 3, wherein the heat-conductive insulating layer comprises AlN, SiC or a high thermal conductivity insulating material.

6. The manufacturing method of claim 1, wherein the heat-conductive adhering layer comprises a bonding material, such as tin paste, tin-silver paste, silver paste, alloys, or a eutectic bonding material.

7. The manufacturing method of claim 1, wherein the plate is removed by laser lift-off process.

8. The manufacturing method of claim 1, wherein after the step of removing the plate, the manufacturing method further comprises a step of:
removing a part of the LED element for exposing a part of the reflective layer.

9. The manufacturing method of claim 8, wherein the step of removing the part of the LED element further comprises steps of:
forming a photoresist layer on the first semiconductor layer;
exposing the photoresist layer by a light via a mask;
removing a part of the photoresist layer to form a patterned photoresist layer;
removing a part of the first semiconductor layer, a part of the light emitting layer and a part of the second semiconductor layer; and
removing the patterned photoresist layer.

10. The manufacturing method of claim 8, wherein after the step of removing the part of the LED element, the manufacturing method further comprises a step of:
forming a first contacting electrode on the fast semiconductor layer.

11. The manufacturing method of claim 8, wherein after the step of removing the part of the LED element, the manufacturing method further comprises a step of:
forming a second contacting electrode on an exposed part of the reflective layer.

12. The manufacturing method of claim 1, wherein the reflective layer is an ohmic contact metal reflective layer, and the reflective layer comprises Pt, Au, Ag, Pd, Ni, Cr, Ti, Al or their combinations.

13. The manufacturing method of claim 1, wherein the steps are performed under a temperature ranging between 25° C. and 300° C.

14. The manufacturing method of claim 1, wherein after the step of attaching the heat-conductive substrate on the heat-conductive adhering layer, the manufacturing method further comprises a step of:
fliping the electroluminescent device.

15. An electroluminescent device, comprising:
a heat-conductive adhering layer;
a heat-conductive substrate attached on one side of the heat-conductive adhering layer;
a reflective layer formed on the other side of the heat-conductive adhering layer;
a light emitting diode (LED) element formed on the reflective layer and exposing part of the reflective layer, the LED element comprising a first semiconductor layer, a light emitting layer, and a second semiconductor layer in contact with the reflective layer in sequence;
a first contacting electrode electrically connected with the first semiconductor layer; and
a second contacting electrode disposed on an exposed part of the reflective layer and electrically connected with the reflective layer.

16. The electroluminescent device of claim 15, further comprising:
a heat-conductive insulating layer formed between the heat-conductive substrate and the heat-conductive adhering layer, or formed between the heat-conductive adhering layer and the reflective layer.

17. The electroluminescent device of claim 16, wherein the heat-conductive insulating layer comprises AlN, SiC or a high thermal conductivity insulating material.

18. The electroluminescent device of claim 15, wherein the heat-conductive adhering layer comprises a bonding material, such as tin paste, tin-silver paste, silver paste, alloys, or a eutectic bonding material.

19. The electroluminescent device of claim 15, wherein the reflective layer is an ohmic contact metal reflective layer, and the reflective layer comprises Pt, Al, Ag, Pd, Ni, Cr, Ti, Al or their combinations.

20. The electroluminescent device of claim 15, wherein the heat-conductive substrate comprises Si, GaAs, GaP, SiC, BN, Al, AlN, Cu, or their combinations.
